(19) United States
(12) Patent Application Publication
(10) Pub. No.: US 2006/0145313 A1
(43) Pub. Date: Jul. 6, 2006

(54) Semiconductor package device having reduced mounting height and method for manufacturing the same

(75) Inventor: Kwan Yul Lee, Gyeonggi-do (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/320,616

(22) Filed: Dec. 30, 2005

(30) Foreign Application Priority Data
Dec. 31, 2004 (KR) 10-2004-0117675

(51) Int. Cl. H01L 23/495

(52) U.S. Cl. 257/666

(57) ABSTRACT

A semiconductor package device including a lead frame including a die pad to which a semiconductor chip is attached and a plurality of terminals for electrical interconnection of the semiconductor chip to an external device. The device also includes a plurality of bonding wires for electrically interconnecting the terminals to the semiconductor chip, a package body for protecting the semiconductor chip, die pad, terminals, and bonding wires, and a plurality of connections bonded to the terminals for electrically interconnecting the semiconductor chip to the external device. The plurality of connections are made of solder balls or bumps and electrically interconnected to board connectors of an external circuit board.

### CROSS REFERENCE TO RELATED APPLICATIONS

This U.S. non-provisional application claims priority under 35 U.S.C. §119 from Korean Patent Application No. 2004-117675, which was filed in the Korean Intellectual Property Office on Dec. 31, 2004, the contents of which are incorporated by reference herein in its entirety.

### BACKGROUND OF THE INVENTION

1. Field of the Invention

The present invention generally relates to semiconductor package technologies and, more particularly to semiconductor package devices and manufacturing method thereof, such package devices having reduced mounting height.

2. Discussion of the Background

Assembly process of semiconductor devices starts with isolation of individual chips from a wafer. Each of the isolated chips is electrically interconnected to a lead frame and encapsulated by a molding compound (package body) for protecting the electrical interconnection and the chip from harmful external environment. The semiconductor chip under the assembly process is referred to as “semiconductor chip device”, while the packaged chip is referred to as “semiconductor package device”.

FIG. 1 is a perspective view of a conventional semiconductor package device of dual in-line package (DIP) structure.

As shown in FIG. 1, an individual semiconductor chip 10 isolated from a wafer (not shown) is attached to a die pad 12 of a lead frame 14 by adhesive such as Ag-epoxy. The lead frame 14 may be made of iron-alloy or copper-alloy. The die pad 12 and leads of the lead frame 14 are coupled by a tie bar. Inner leads of the lead frame 14 are electrically interconnected to the semiconductor chip device 10 by bonding wires 16, which are fine wires made of gold (Au). The inner leads of the lead frame and the semiconductor chip are protected by package body 18 made of plastic resin (e.g., epoxy molding compound). After forming the package body 18, the outer leads of the lead frame 14 are bent to have a predetermined shape. The shape of bent outer leads depends upon the mounting structure of the package device 20 on an external device (e.g., printed circuit board).

The mounting structures of the package device 20 are diverse. For instance, FIG. 2a (a) and (b) show dual in-line package (DIP) structure 20a and pin grid array package (PGA) structure 20b, respectively, FIG. 2b (a), (b), (c) illustrate J-shaped bent outer leads structure 20c, gull-wing structure 20d, and straight lead structure 20e, and FIG. 2c shows a mounting structure 20f in which the outer leads do not protrude from the package body rather they are just exposed to be soldered by tin-lead solder or lead-free solder.

The package devices having various mounting structures are mounted on the circuit board 25 as shown in FIGS. 2a to 2c. Therefore, the height of the package devices 20a to 20f are determined by the thickness of the package body 18 added by the bent structure of outer leads or soldering structure between outer leads and circuit board. This means that the mounting height of the conventional package device is limited to the mounting structure and hence if the mounting structure is fundamentally modified from the conventional one, dramatic reduction in the mounting height is possible.

### SUMMARY OF THE INVENTION

It is therefore the purpose of the present invention to provide new mounting structure of semiconductor package device that can dramatically reduce the package mounting height.

Another purpose of the present invention is to provide semiconductor package structure and manufacturing method thereof that can achieve the miniaturization of electronic devices.

According to one aspect of the present invention, a semiconductor package device comprises: a lead frame including a die pad to which a semiconductor chip is attached and a plurality of terminals for electrical interconnection of the semiconductor chip to an external device; a plurality of bonding wires for electrically interconnecting the terminals to the semiconductor chip; a package body for protecting the semiconductor chip, die pad, terminals, and bonding wires; and a plurality of connections bonded to the terminals for electrically interconnecting the semiconductor chip to the external device. The plurality of connections are made of solder balls or bumps and electrically interconnected to board connectors of an external circuit board. Since the package device is received in a space in the circuit board and does not have connections protruding from either top or bottom surface of the package body, there is not additional mounting height by the package device in the circuit board.

According to other aspect of the present invention, method for manufacturing a semiconductor package device comprising steps of: preparing a lead frame that includes a die pad and a plurality of terminals; attaching a semiconductor chip to the die pad; electrically interconnecting the semiconductor chip attached to the die pad to the plurality of terminals; bonding a plurality of connections to the terminals, said plurality of connections being for electrically interconnect the semiconductor chip to an external device; and forming a package body for protecting the semiconductor chip, die pad, terminals, and electrical interconnection between the semiconductor chip and the terminals.

### BRIEF DESCRIPTION OF DRAWINGS

FIG. 1 is a perspective view of the conventional semiconductor package device of DIP (Dual In-line Package) structure.

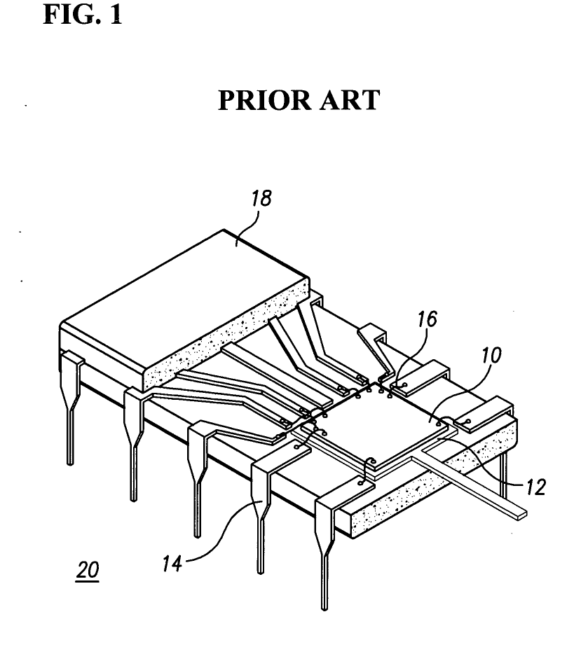

FIGS. 2a to 2c are cross-sectional views for showing the conventional various mounting structures of the semiconductor package devices.

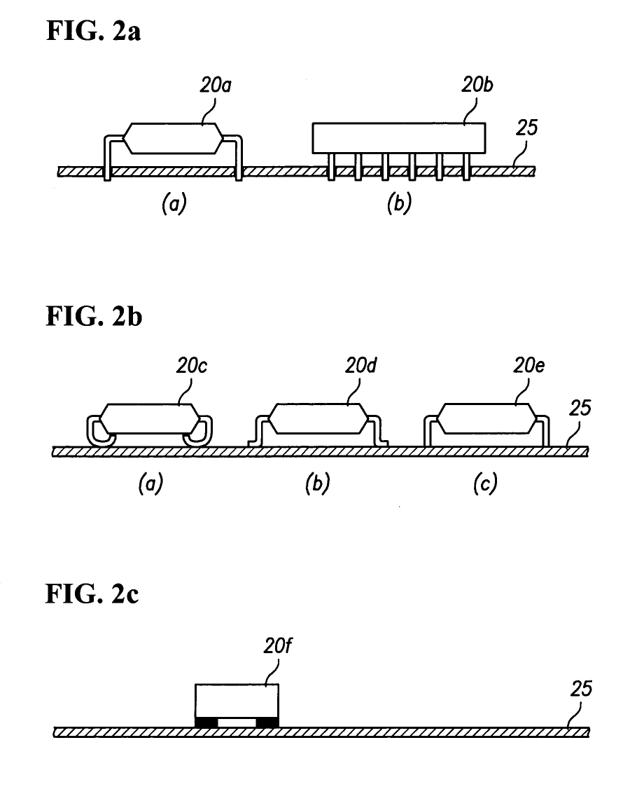

FIG. 3a is a schematic diagram for showing the interior structure of a semiconductor package device according to the present invention.

FIGS. 3b and 3c are side and front views of the package device of FIG. 3a, respectively.

FIG. 4 is a cross-sectional view for illustrating the interior structure of the semiconductor package device according to the present invention.

FIG. 5 is a schematic diagram for showing the semiconductor package device mounted on the circuit board.

### DETAILED DESCRIPTION OF EXEMPLARY EMBODIMENTS OF THE INVENTION

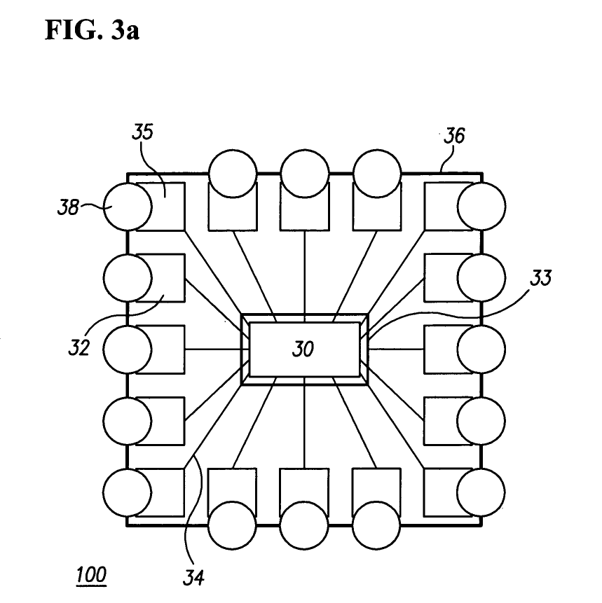

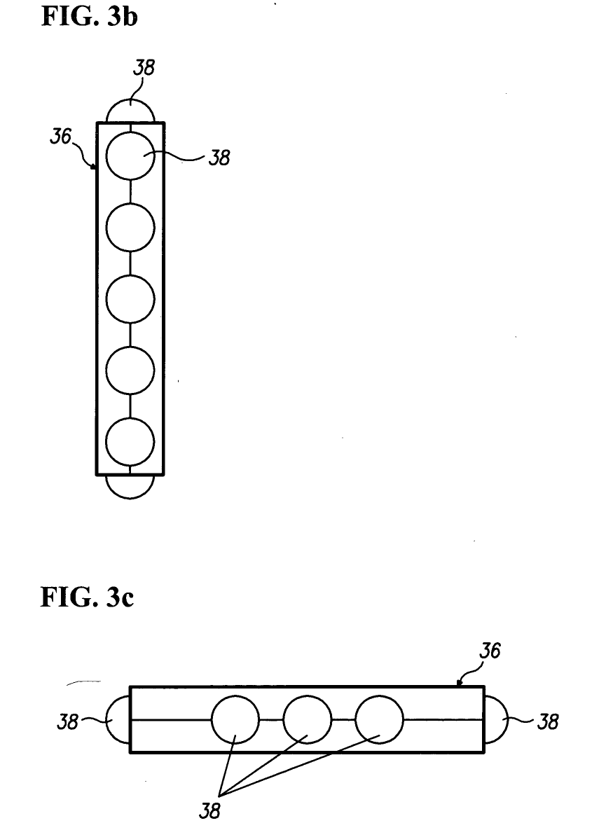

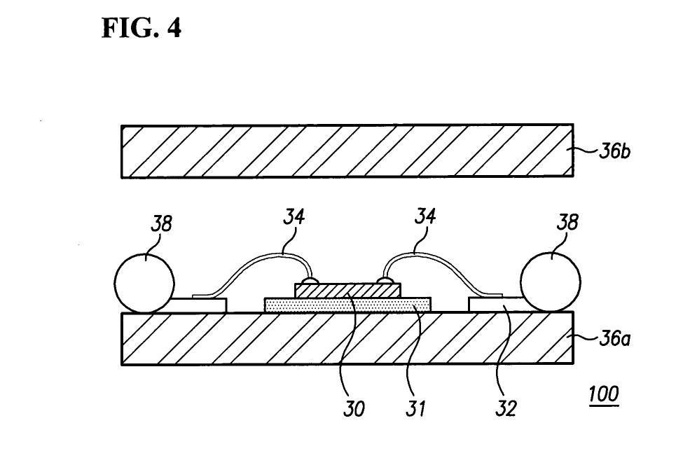

FIG. 3a is a schematic diagram showing the interior structure of the semiconductor package device according to the present invention, FIGS. 3b and 3c are side and front views of the package device of FIG. 3a, respectively, and FIG. 4 is a cross-sectional view of the interior structure of the semiconductor package device.

Referring to FIGS. 3a-c and 4, the package device 100 of the present invention comprises a semiconductor chip 30, a lead frame 32, bonding wires 34 and external connections 38. The lead frame 32 includes a die pad 33 to which the semiconductor chip 30 is attached by adhesive such as Ag-epoxy and terminals 35 to which the external connections 38 are bonded. The terminals 35 correspond to the lead frame leads of the conventional package structure as explained above. The lead frame 32 can be made of iron-nickel alloy, iron-chrome alloy (e.g., Alloy-42 or 29Ni—17Co—Fe alloy), or copper alloy. The surface of the lead frame can be plated with Au or Ag to improve the conductivity.

The bonding wires 34, made of e.g., Au, electrically interconnect electrode pads (not shown) of the semiconductor chip 30 and the terminals 35 of the lead frame 32. Each of the bonding wires 34 are ball-bonded to the electrode pads and wedge-bonded to the terminals 35. Therefore, electronic circuits in the semiconductor chip 30 can electrically communicate with external devices (e.g., a circuit board) through the electrode pads, bonding wires 34 and terminals 35.

The package body 36 protects the semiconductor chip, electrical connection structure between the bonding wires and the chip from contaminants and moisture, and electrically insulates each of the terminals 35. The package body 36 can be formed by epoxy resin or silicon resin.

Referring to FIG. 4, the package body 36 includes lower and upper bodies 36a and 36b. The lower body 36a can be formed by a transfer molding method in which lead frame 32 having the semiconductor chip 30 attached to the die pad 31 is placed on a mold and liquid epoxy resin is injected into a cavity of the mold under high temperature and high pressure environment to form the lower body 36a.

After forming the lower body 36a, a plurality of connections 38 are bonded to the terminals 35. In an embodiment of the present invention, the connections 38 are solder balls as shown in FIGS. 3 and 4, which can be made of e.g., tin-lead (Sn—Pb) alloy or lead-free solder. It should be noted that the shape of the connection 38 is not limited to the ball, and the connection 38 can be a solder bump having a cube shape. The bonding of the connections 38 to the terminals 35 includes a reflow soldering. When the connections 38 are bonded to the terminals 35, the upper body 36b is coupled to the lower body 36a. According to one embodiment of the present invention, the upper body 36b is constructed as a lid to cover the lower body 36b as shown in FIG. 4. Alternatively, the upper body 36 can be formed at the same time when the lower body 36a is molded. In this embodiment, liquid epoxy resin injects into and fills the space on the lower body 36a to form the upper body 36.

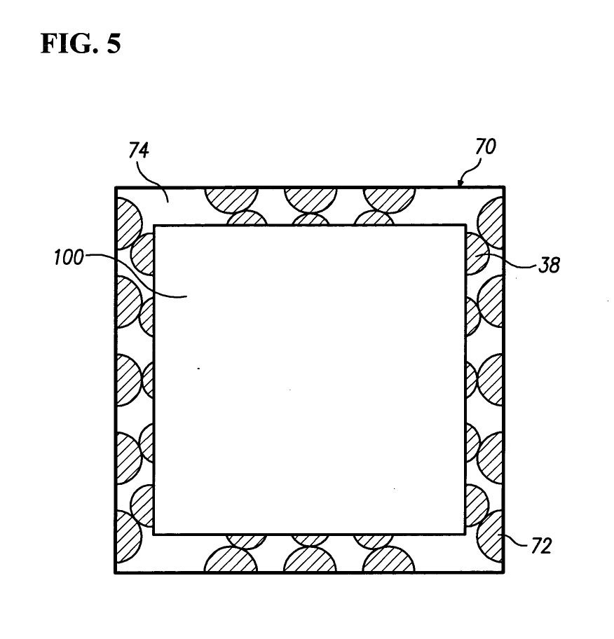

The package device of the present invention has the connections 38 partly protruding from the package body 36. More specifically, the connections 38 are exposed at side surfaces of the package body 36 as shown in FIGS. 3a and 3b, but they do not protrude from the package body 36 at either top or bottom surface. With this structure, the package device, when mounted on a circuit board, has no effect on the increase of the mounting height of the package device. In other words, as shown in FIG. 5, the package device 100 is received in a space 74 of the circuit board 70, and therefore any increase of mounting height due to the package device 100 does not occur in the circuit board.

The package device 100 is electrically interconnected to the circuit board 70 through the plurality of connections 38 and board connectors 72 that are connected to internal wirings of the circuit board. In an embodiment of the present invention, the board connectors 72 are formed of solder balls. Alternatively, the board connectors 72 can be formed of metal plates.

Although certain apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

What is claimed is:

1. A semiconductor package device comprising:
a lead frame including a die pad to which a semiconductor chip is attached and a plurality of terminals for electrical interconnection of the semiconductor chip to an external device;
a plurality of bonding wires for electrically interconnecting the terminals to the semiconductor chip;
a package body for protecting the semiconductor chip, die pad, terminals, and bonding wires; and
a plurality of connections bonded to the terminals for electrically interconnecting the semiconductor chip to the external device, said plurality of connections protruding from the package body at side surface of the package body.

2. The semiconductor package device of claim 1, where the plurality of connections are solder balls.

3. The semiconductor package device of claim 1, wherein the package body comprises a lower body on which the lead frame is placed, and an upper body coupled to the lower body.

4. A method for manufacturing a semiconductor package device, said method comprising steps of:
preparing a lead frame that includes a die pad and a plurality of terminals;
attaching a semiconductor chip to the die pad;
electrically interconnecting the semiconductor chip attached to the die pad to the plurality of terminals;
bonding a plurality of connections to the terminals, said plurality of connections being for electrically interconnecting the semiconductor chip to an external device; and
forming a package body for protecting the semiconductor chip, die pad, terminals, and electrical interconnection between the semiconductor chip and the terminals, wherein the plurality of connections protrude from the package body at side surfaces of the package body.
